(19) United States
(12) Patent Application Publication
(10) Pub. No.: US 2026/0372027 A1
(43) Pub. Date: Nov. 19, 2026

(54) MOS-CAPACITOR FORMED ON PARTIAL SOI STRUCTURE, SEMICONDUCTOR DEVICE, AND METHOD OF FORMING THE SAME

(71) Applicant: Taiwan Semiconductor Manufacturing Company, Ltd., Hsinchu (TW)

(72) Inventors: Chung-Lei Chen, Hsinchu (TW); Anhao Cheng, Taichung (TW); Meng-I Kang, Changhua County (TW); Yen-Liang Lin, Tainan (TW)

(21) Appl. No.: 19/754,333

(22) Filed: Jul. 27, 2026

Related U.S. Application Data
(62) Division of application No. 17/823,508, filed on Aug. 30, 2022.

(51) Int. Cl. H10P 90/00; H10D 86/01; H10W 10/00; H10W 10/10; H10W 10/17

(52) U.S. Cl. CPC H10P 90/1914; H10D 86/01; H10P 90/1906; H10W 10/014; H10W 10/061; H10W 10/17; H10W 10/181

(57) ABSTRACT

A method for forming a semiconductor device includes providing a semiconductor substrate, implanting n-type impurities into a device region in the semiconductor substrate to form an implanted region and an un-implanted region. The method also includes forming an epitaxial layer on the semiconductor substrate and forming a trench surrounding the device region in direct contact with the implanted region. The method further includes performing a selective lateral etch through the trench to remove the implanted region to form a cavity under the epitaxial layer. The un-implanted region is retained to form a pillar under the epitaxial layer. Next, an insulating material is disposed in the cavity and the trench. The method forms a single crystalline region that is separated from the semiconductor substrate by the insulating material except at the pillar.

### CROSS-REFERENCES TO RELATED APPLICATIONS

The present application is a divisional application of U.S. patent application Ser. No. 17/823,508, filed Aug. 30, 2022, and entitled “MOS-CAPACITOR FORMED ON A PARTIAL SOI STRUCTURE, SEMICONDUCTOR DEVICE, AND METHOD OF FORMING THE SAME,” the entire disclosure of which is incorporated herein by reference.

### BACKGROUND

MOS (Metal-oxide-semiconductor) capacitors are widely used in integrated circuit (IC) designs, for example, for input/output (I/O) signal noise reduction.

Metal-oxide-semiconductor (MOS) capacitors are frequently formed as part of the complementary metal oxide semiconductor (CMOS) process. In a CMOS process, transistors are typically formed by providing an active area with doped source/drain regions in the substrate, a gate insulating layer over the substrate, and a gate electrode over the gate insulating layer. Contacts (e.g., tungsten) connect the source/drain regions and gate electrode with a conductive interconnect structure having several horizontal conductive pattern layers (typically referred to as M1, M2, etc.) and vertical via layers formed within a plurality of inter-metal dielectric (IMD) layers.

In some cases, to integrate the MOS capacitor fabrication into the same process, the top electrode of the MOS capacitor is formed as part of the gate layer. The capacitor dielectric is formed as part of the gate insulation layer. The anode contact of the capacitor is formed on the top electrode of the capacitor. A cathode contact connects to the source/drain and bulk substrate.

As transistor dimensions (including gate insulation layer thickness) shrink, leakage becomes a problem, and the gate insulation layer becomes more vulnerable to breakdown. To reduce leakage in advanced, smaller transistors, high-k metal gate structures have been considered. The traditional silicon dioxide gate insulating layer is replaced with a relatively thicker layer of a high-k dielectric material, such as hafnium silicate, zirconium silicate, hafnium dioxide or zirconium dioxide. The polycrystalline silicon gate electrode material can be replaced with a metal, such as titanium nitride, tantalum nitride, or aluminum nitride.

Advanced methods of fabricating MOS capacitors, which are compatible with a high-k metal gate process, are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor capacitor device, in accordance with some embodiments.

FIG. 2A is a top view of a portion of the semiconductor capacitor device of FIG. 1, in accordance with some embodiments.

FIG. 2B is another cross-sectional view of the semiconductor capacitor device of FIG. 1, in accordance with some embodiments.

FIG. 3 is a simplified flowchart illustrating a method for forming a semiconductor device, in accordance with some embodiments.

FIG. 4A is a top view and FIGS. 4B and 4C are cross-sectional views illustrating an intermediate process of a method for forming a semiconductor device, in accordance with some embodiments.

FIG. 5A is a top view and FIGS. 5B and 5C are cross-sectional views illustrating another intermediate process of a method for forming a semiconductor device, in accordance with some embodiments.

FIG. 6A is a top view and FIGS. 6B and 6C are cross-sectional views illustrating another intermediate process of a method for forming a semiconductor device, in accordance with some embodiments.

FIG. 7A is a top view and FIGS. 7B and 7C are cross-sectional views illustrating another intermediate process of a method for forming a semiconductor device, in accordance with some embodiments.

FIG. 8A is a top view and FIGS. 8B and 8C are cross-sectional views illustrating another intermediate process of a method for forming a semiconductor device, in accordance with some embodiments.

FIG. 9A is a top view and FIGS. 9B-9D are cross-sectional views illustrating another intermediate process of a method for forming a semiconductor device, in accordance with some embodiments.

FIG. 10A is a top view and FIGS. 10B-10C are cross-sectional views illustrating another intermediate process of a method for forming a semiconductor device, in accordance with some embodiments.

FIG. 11 is a simplified layout diagram illustrating an example of an integrated circuit including embedded SOI regions, in accordance with some embodiments.

FIG. 12 is a simplified layout diagram illustrating another example of an integrated circuit including embedded SOI regions, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

In some applications, the MOS capacitor uses heavy N+ doping in a semiconductor region formed in a p-well as the bottom electrode for the capacitor to enhance the device performance. As an example, the N+ doping can be achieved using ion implantation. The heavily doped bottom plate can reduce the depleted area. However, the heavy N+ doping can create leakage paths in MOS capacitors and impact the performance of the capacitor.

In accordance with some embodiments, an embedded SOI (silicon-on-insulator or semiconductor-on-insulator) structure is formed and used in an MOS capacitor structure for reducing the leakage. A method is provided for forming the embedded SOI structure in a selected region of a semiconductor substrate. In some embodiments, the selected region is implanted with n-type dopants to form an implanted region and an un-implanted region. An epitaxial layer is formed over the implanted region. A trench is formed that surrounds the selected region to expose at least a portion of the implanted region. A selective silicon lateral etching process is used to remove the implanted region to create a cavity under the epitaxial layer. The trench and the cavity are filled with an insulation material. The epitaxial layer in the selected region now resides over the insulating material, forming an SOI structure. The un-implanted region is retained during the selective etching process to form a pillar protruding from the substrate and connects the epitaxial layer to the substrate. The pillar connects the epitaxial layer to the substrate during the selective etching process to prevent the epitaxial layer from peeling off. An MOS capacitor is then formed using the SOI structure as its bottom capacitor plate. A benefit of this method is that the capacitor leakage could be greatly reduced by the SOI structure, which is isolated from the substrate, except at the pillar.

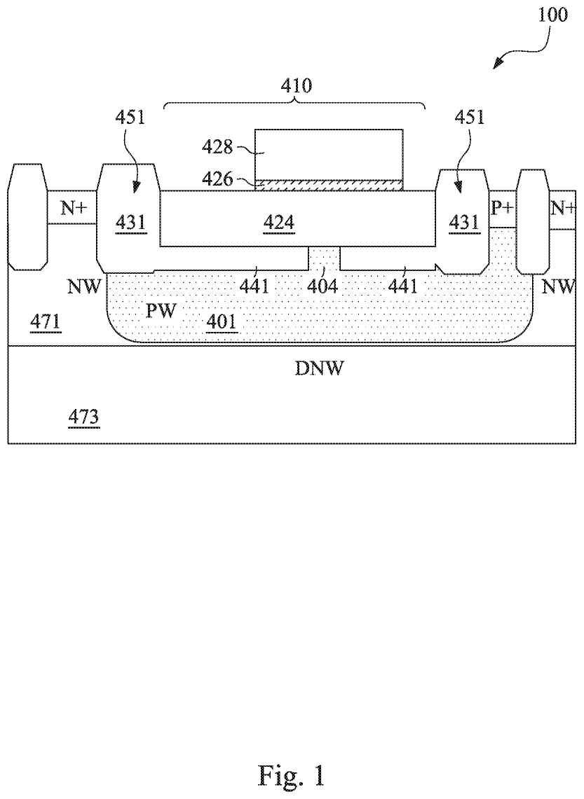

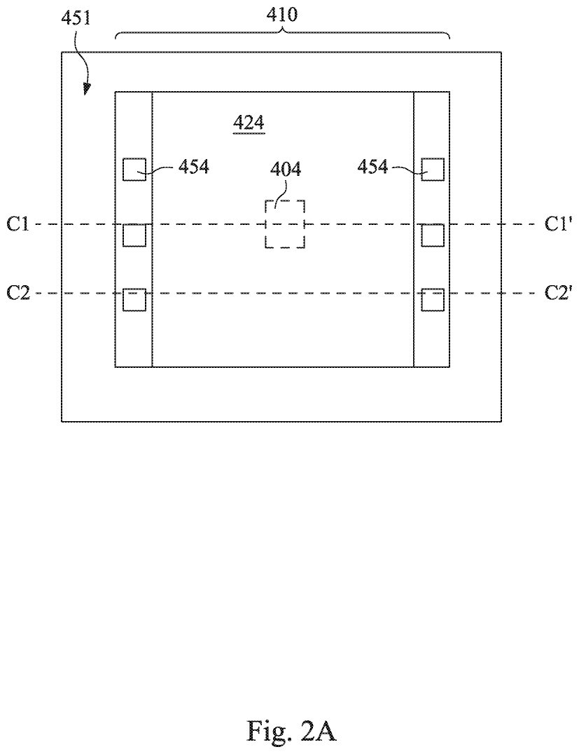

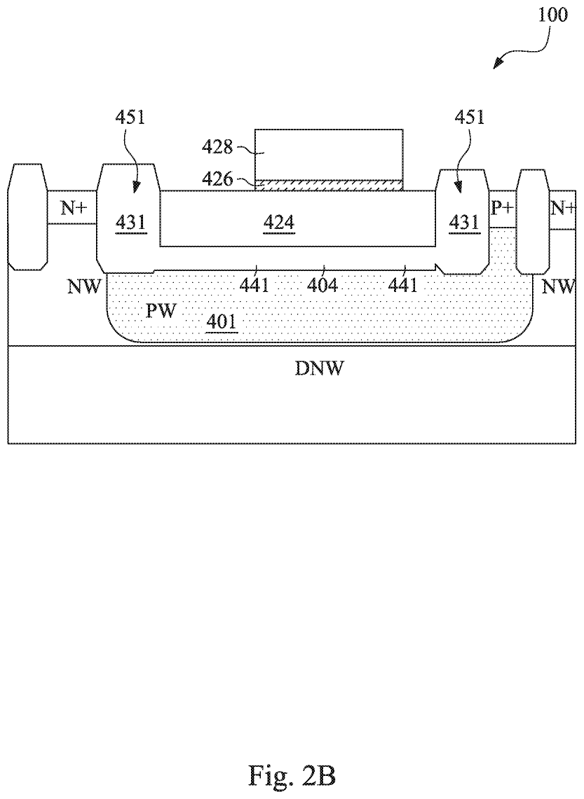

FIG. 1 is a cross-sectional view of a semiconductor capacitor device, in accordance with some embodiments. FIG. 2A is a top view of a portion of the semiconductor capacitor device of FIG. 1, in accordance with some embodiments. FIG. 2B is another cross-sectional view of the semiconductor capacitor device of FIG. 1, in accordance with some embodiments.

As shown in FIGS. 1, 2A, and 2B, a semiconductor capacitor device 100 includes a semiconductor substrate 401, and a recess formed by trenches 431 and cavity 441 in the semiconductor substrate 401. An insulating material 451 is disposed in the recess. A semiconductor pillar 404 protrudes from the semiconductor substrate 401 and is surrounded by the insulating material 451. Semiconductor capacitor device 100 also includes a single crystalline semiconductor layer 424 disposed on the semiconductor pillar 404 to form a bottom plate of the capacitor device. A capacitor dielectric layer 426 is disposed on the bottom plate, and a top plate 428 of the capacitor device 100 is disposed on the capacitor dielectric layer 426.

In this example, substrate 401 refers to a p-well in a silicon substrate. For example, FIGS. 1, 2A, and 2B, show a substrate, which is a p-well (PW) formed in an n-well (NW) 471, which is disposed in a deep n-well (DNW) 473. In some embodiments, the pillar 404 has a dimension of 40 nm or larger.

The top plate 428 of the capacitor can be a metal gate or polysilicon gate. The p-well and the insulating material 451 in the trench 431 and cavity 441 around semiconductor layer 424, which is the MOS capacitor low electrode, helps to reduce the capacitor leakage.

FIG. 2A is a top view of a portion of the semiconductor capacitor device of FIG. 1, in accordance with some embodiments. FIG. 2A shows the single crystalline semiconductor layer 424, also referred to as the SOI region, surrounded by the isolation material 451. The dotted line block marked by 404 is the location of the pillar 404 that is not visible in FIG. 2A. Further, FIG. 2A also shows contacts 454 to the capacitor bottom plate formed by the crystalline semiconductor layer 424, which is also referred to as the SOI region.

FIG. 2A shows two cut lines C1-C1′ and C2-C2′. FIG. 1 is a cross-sectional view of the structure along cut line C1-C1′ showing the pillar 404, and FIG. 2B is a cross-sectional view of along cut line C2-C2′ where the pillar 404 is not visible.

The dimensions of the capacitor device 100 can be adjusted according to the application. In some embodiments, the lateral dimension of the capacitor device is between 0.1 um to 20 um. In some embodiments, the lateral dimension of the capacitor device is between 1 um to 2 um. In some embodiments, the SOI layer 424 is formed by an epitaxial process and has a thickness between about 1 nm to about 100 nm. The depth of the trench 431 is between about 1000 Å to about 5000 Å. In some embodiments, the depth of the trench 431 is about 3000 Å. In some embodiments, the thickness of the cavity 441 under the SOI layer 424 is about 100 Å to about 1,500 Å. In some embodiments, the thickness of the cavity 441 under the SOI layer 424 is about 150 Å to about 200 Å. In some embodiments, the pillar 404 has a lateral dimension of about 20 nm to about 60 nm. In some embodiments, the pillar 404 has a lateral dimension of about 40 nm.

Capacitor device 100 as described above in connection with FIGS. 1, 2A, and 2B is formed in a CMOS (Complementary Metal-Oxide-Semiconductor) compatible process and can be used as part of a CMOS circuit. In some embodiments, the device includes additional semiconductor pillars protruding from the semiconductor substrate, the additional semiconductor pillars being in direct contact with the single crystalline semiconductor layer. In some embodiments, the insulating material includes silicon oxide. In some embodiments, the capacitor dielectric layer includes silicon oxide.

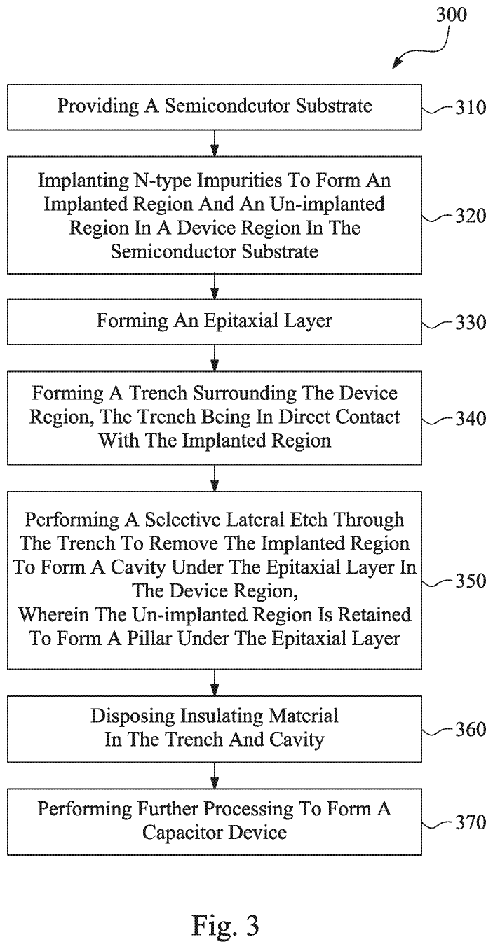

FIG. 3 is a simplified flowchart illustrating a method for forming a semiconductor device, in accordance with some embodiments. As shown in FIG. 3, a method 300 for forming a semiconductor device is summarized below.
310: providing a semiconductor substrate, the semiconductor substrate comprising p-type impurities;
320: implanting n-type impurities into a device region in the semiconductor substrate to form an implanted region and an un-implanted region in the device region;
330: forming an epitaxial layer on the device region in the semiconductor substrate;
340: forming a trench surrounding the device region, the trench extending through the epitaxial layer into the semiconductor substrate, the trench being in direct contact with the implanted region;
350: performing a selective lateral etch through the trench to remove the implanted region to form a cavity under the epitaxial layer in the device region, wherein the un-implanted region is retained to form a pillar under the epitaxial layer;
360: disposing insulating material in the trench and the cavity; and
370: performing further processing to form a capacitor device.

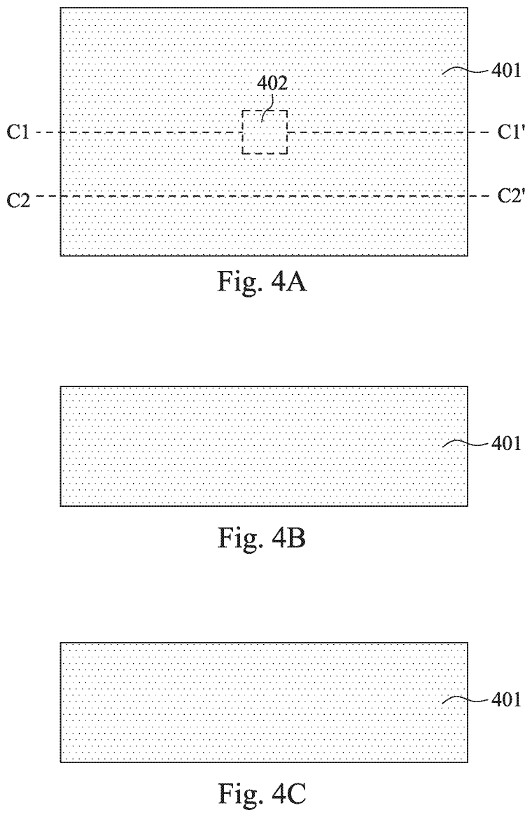

The method 300 for forming a semiconductor device outlined in the flowchart in FIG. 3 is described below with reference to FIGS. 4A-9D. In the description below, various device dimensions, and ranges of process parameters, such temperature, pressure, time duration, implant dose and energy, etc., will be provided as examples. It is understood that the dimensions, numbers, and parameter values are not meant to be limiting, and other suitable dimensions, numbers, and parameter values can also be used.

FIG. 4A is a top view and FIGS. 4B and 4C are cross-sectional views illustrating an intermediate process of a method for forming a semiconductor device, in accordance with some embodiments. In method 300 of FIG. 3, in process 310, a semiconductor substrate 401 is provided, as shown in FIGS. 4A, 4B, and 4C. FIG. 4A is a top view of substrate 401 that also shows two cut lines C1-C1′ and C2-C2′. Cut line C1-C1′ crosses an area 402, which designates a region where a pillar is to be formed. Cut line C2-C2′ does not cross area 402. FIG. 4B is a cross-sectional view of substrate 401 along cut line C1-C1′, and FIG. 4C is a cross-sectional view of substrate 401 along cut line C2-C2′. FIGS. 4B and 4C appear similar at this stage before the pillar is formed.

The substrate 401 may be a bulk semiconductor substrate, which may be doped (e.g., with a p-type or an n-type dopant) to form various well regions or doped regions therein, or undoped. The substrate may be made of silicon or another semiconductor material. For example, the substrate can be a silicon wafer. In some examples, the substrate is made of a compound semiconductor such as silicon germanium (SiGe), silicon carbide (SiC), gallium arsenic (GaAs), indium arsenide (InAs), or indium phosphide (InP), or another suitable compound semiconductor. In some examples, the substrate is made of an alloy semiconductor such as gallium arsenide phosphide (GaAsP), aluminum indium arsenide (AlInAs), aluminum gallium arsenic (AlGaAs), gallium indium arsenide (GaInAs), gallium indium phosphide (GaInP), or gallium indium arsenide phosphide (GaInAsP), or another suitable alloy semiconductor.

In some embodiments, the semiconductor substrate is a silicon substrate and includes p-type impurities. In some embodiments, such as those shown in FIGS. 1, 2A, and 2B, substrate 401 can be a portion of a p-well in a silicon substrate. For example, FIGS. 1, 2A, and 2B shows a p-well 401 formed in an n-well 471, which is disposed in a deep n-well 473.

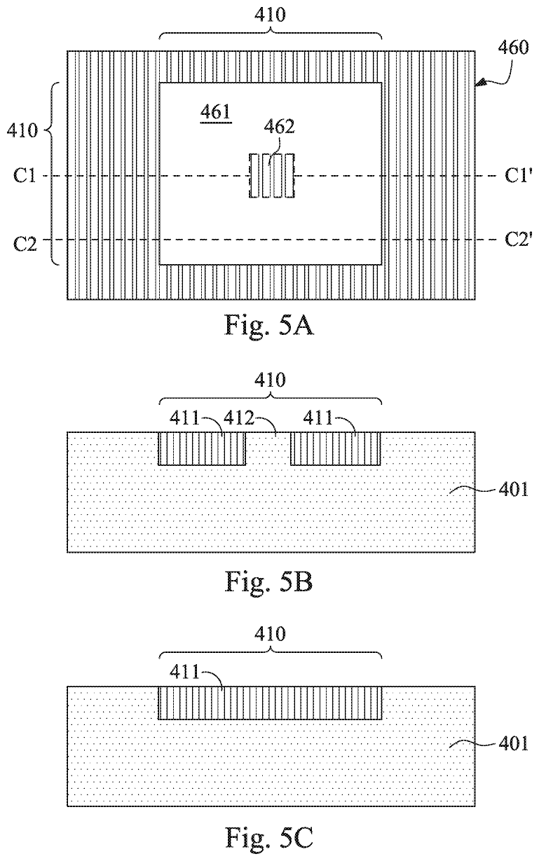

FIG. 5A is a top view and FIGS. 5B and 5C are cross-sectional views illustrating another intermediate process of a method for forming a semiconductor device, in accordance with some embodiments. In process 320, the method 300 includes implanting n-type impurities into a device region in the semiconductor substrate to form an implanted region and an un-implanted region in the device region. FIG. 5A illustrates a top view of a mask 460 for ion implantation. In processing, mask 460 is formed on a top surface of substrate 401.

Depending on the embodiments, mask 460 can be a photoresist mask or a hard mask formed by a patterned layer of dielectric material. In some examples, the hard mask is made of silicon oxide (SiO₂), silicon carbon nitride (SiCN), silicon oxycarbide (SiOC), silicon oxycarbon nitride (SiOCN) silicon nitride (SiN or Si₃N₄), or another suitable material. The hard mask is formed using deposition, photolithography, and etching processes. The etching processes may include a reactive ion etch (RIE), neutral beam etch (NBE), inductive coupled plasma (ICP) etch, or another suitable etch process, or a combination thereof.

As shown in FIG. 5A, mask 460 includes an open region 461 and a blocked region 462. The open region 461 of mask 460 allows impurities to be implanted into a device region 410 in substrate 401. The blocked region 462 prevents any impurity implantation. In method 300, the implantation process involves implanting an n-type dopant into the substrate through mask 460. N-type impurities include arsenic (Ar), phosphorus (P), antimony (Sb), or other suitable n-type dopants.

FIG. 5B is a cross-sectional view of substrate 401 after the ion implantation step along cut line C1-C1′, and FIG. 5C is a cross-sectional view of substrate 401 after the ion implantation step along cut line C2-C2′. FIGS. 5B and 5C illustrate implanted regions 411 and an un-implanted region 412 in the device region 410 of substrate 401. As described below, the implanted region 411 will be etched off to form a cavity. In some embodiments, the depth of the cavity is about 100 Å to about 1,500 Å. Further, the etch rate can vary with the dopant concentration. Therefore, the implantation energy and dose can be adjusted accordingly.

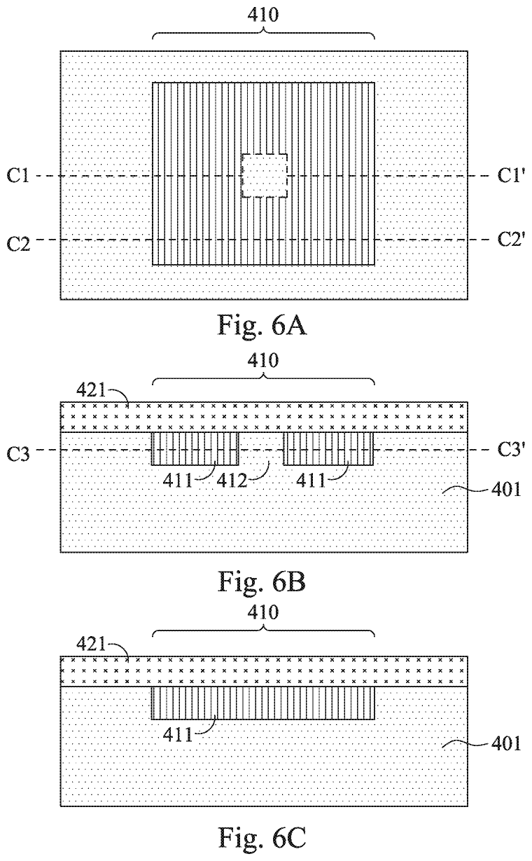

FIG. 6A is a top view and FIGS. 6B and 6C are cross-sectional views illustrating another intermediate process of a method for forming a semiconductor device, in accordance with some embodiments. FIG. 6B is a cross-sectional view of substrate 401 after the ion implantation step along cut line C1-C1′, and FIG. 6C is a cross-sectional view of substrate 401 after the ion implantation step along cut line C2-C2′.

At process 330 of method 300, an epitaxial layer 421 is formed in the device region 410 in the semiconductor substrate 401. In embodiments in which the substrate 401 is a silicon substrate or a p-well formed in a silicon substrate, the epitaxial layer 421 is an epitaxial silicon layer with p-type dopant, for example, by in-situ doping. In some embodiments, epitaxial layer 421 has a thickness between about 1 nm to about 100 nm. However, the thickness can vary depending on the embodiments.

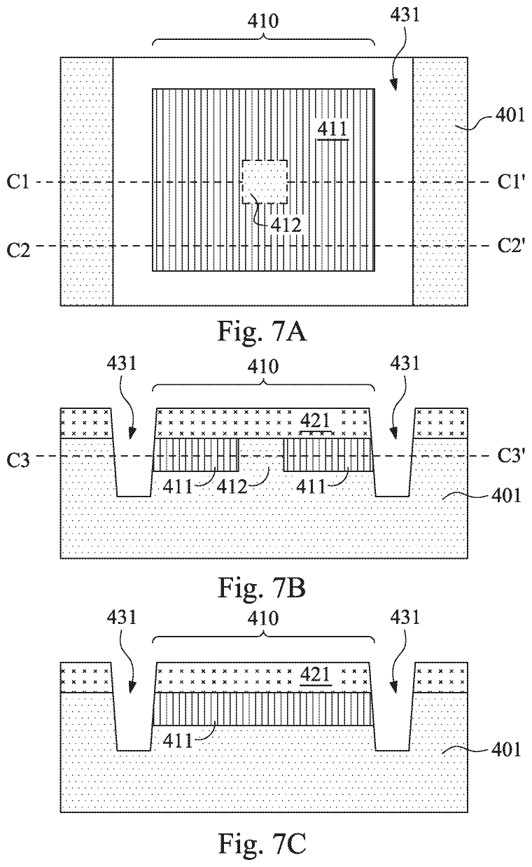

FIGS. 7A, 7B, and 7C are cross-sectional views illustrating another intermediate process of a method for forming a semiconductor device, in accordance with some embodiments. In process 340, method 300 includes forming a trench surrounding the device region. As shown in FIGS. 7A-7C, a trench 431 is formed surrounding the device region 410 extending through the epitaxial layer into the semiconductor substrate. FIG. 7A shows two cut lines C1-C1′ and C2-C2′, and FIG. 7B shows a third cut line C3-C3′. FIG. 7B is a cross-sectional view of the structure along cut line C1-C1′ shown in FIG. 7A, and FIG. 7C is a cross-sectional view of along cut line C2-C2′. FIG. 7A is a cross-sectional view of the structure along cut line C3-C3′ shown in FIG. 7B.

As shown in FIGS. 7A-7C, trench 431 surrounds the device region 410, which includes implanted region 411 and un-implanted region 412. In various embodiments, the trench 431 is in direct contact with the implanted region 411. In the example of FIGS. 7A-7C, trench 431 is in direct contact with the implanted region at all sides of the periphery of the implanted region. In this case, the trench 431 surrounds the epitaxial layer 421 on all sides. However, in some embodiments, trench 431 is in direct contact with only a portion of the implanted region. For example, in some embodiments, a portion of the trench 431 may be separated from the implanted region 411 by the un-implanted region 412.

In some embodiments, etching a substrate to form the trench 431 includes forming an etching mask that includes trench patterns and etching the substrate through the etching mask. One or more etching processes, for example, may be used, including dry etching process(es) such as a plasma etching, reactive ion etching (RIE), wet etching process(es), or a combination thereof. In some embodiments, the dry plasma etch comprises a bombarding the substrate with ions (e.g., fluorocarbons, oxygen, chlorine, nitrogen, argon, helium, etc.) that dislodge portions of the material from the substrate.

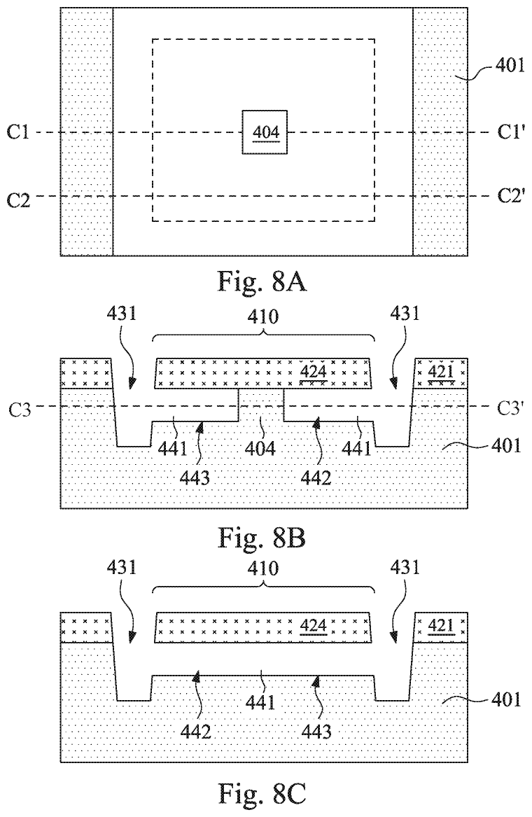

FIGS. 8A, 8B, and 8C are cross-sectional views illustrating another intermediate process of a method for forming a semiconductor device, in accordance with some embodiments. In process 350, the method 300 performs a selective lateral etch through the trench to remove the implanted region to form a cavity under the epitaxial layer in the device region, wherein the un-implanted region is retained to form a pillar under the epitaxial layer. FIG. 8A shows two cut lines C1-C1′ and C2-C2′, and FIG. 8B shows a third cut line C3-C3′. FIG. 8B is a cross-sectional view of the structure along cut line C1-C1′ shown in FIG. 8A, and FIG. 8C is a cross-sectional view of along cut line C2-C2′ shown in FIG. 8A. FIG. 8A is a cross-sectional view of the structure along cut line C3-C3′ shown in FIG. 8B.

As shown in FIGS. 8B and 8C, a cavity 441 is formed under the epitaxial layer 421 in the device region 410 after the implanted region 411 in FIGS. 7B and 7C is removed by a selective lateral etch through the trench 431. The un-implanted region 412 in FIGS. 7B and 7C is retained to form a pillar 404 under the epitaxial layer 421.

FIGS. 8B-8C illustrate a semiconductor device including a semiconductor substrate 401 and a recess 442 formed by trench 431 and cavity 441 in the semiconductor substrate 401. A portion of the semiconductor substrate 401 protruding from a bottom 443 of the recess forms a semiconductor pillar 404, which is surrounded by the recess. A single crystalline semiconductor layer 424 is disposed on the pillar 404. As shown in FIG. 8B, the single crystalline semiconductor layer 424 is in direct contact with the semiconductor substrate 401 through the pillar 404, and is otherwise separated from the semiconductor substrate 401 by the recess 442.

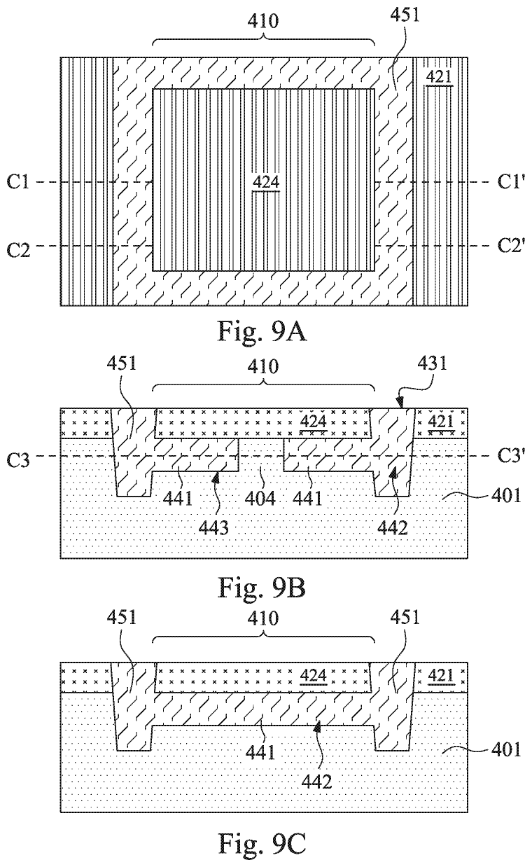

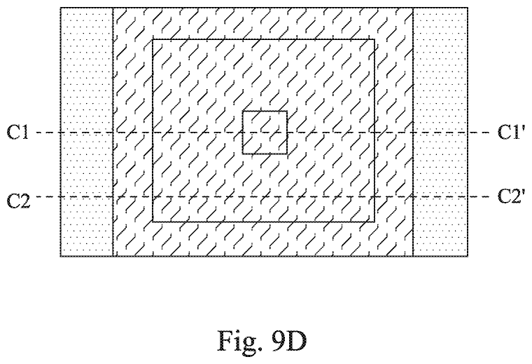

In FIGS. 8A-8C, the single crystalline semiconductor layer 424 is an example of a silicon-on-insulator or semiconductor-on-insulator (SOI) structure. In this case, the insulator is a cavity that contains ambient air. An example of an SOI structure on a dielectric material is described below with reference to FIGS. 9A-9D. As described above, the single crystalline semiconductor layer 424 is formed by a silicon epitaxial growth process. Therefore, the term “single crystalline” as used herein refers to the layer of epitaxial silicon, subject to the crystalline quality achievable by the epitaxial process.

In some embodiments, the cavity is formed by etchants entering the trench 431 and etches the implanted region 411, which is below the SOI layer 424. Therefore, the depth of SOI layer 424 is not greater than the depth of the trench 431. Depending on the embodiments, the trench 431 can have a depth of up to about 3000 Å. In some embodiments, the pillar 404 has a lateral dimension of about 20 nm to about 60 nm. In some embodiments, the pillar 404 has a lateral dimension of about 40 nm. The pillar 404 has a lateral dimension of about 20 nm to about 60 nm.

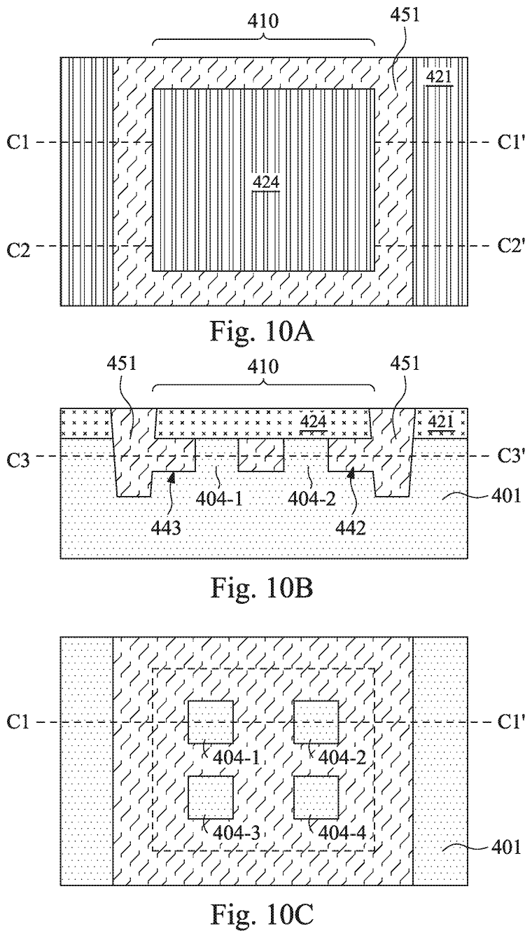

In some embodiments, the pillar 404 is used to connect the SOI layer 424 to the substrate after the cavity 441 is formed under the SOI layer 424. Without the pillar 404, the single crystalline semiconductor layer 424 will peel off. In some embodiments, the capacitor device has one pillar. In other embodiments, the capacity device can have two or more pillars, as explained further with reference to FIGS. 10A-10C. In the embodiments with multiple pillars, each pillar can be smaller than, e. g., 40 nm in lateral dimensions.

In some embodiments, the selective etch used in process 350 of method 300 is accomplished using an etch process that etches an n-type semiconductor material at a substantially faster etch rate than a p-type semiconductor material or an un-doped semiconductor material. In some embodiments, the implanted region 411 in FIGS. 7B and 7C is heavily doped n+ silicon, the rest of the substrate 401 is p-type silicon, and the epitaxial layer 421 is also doped p-type. In these embodiments, the selective lateral etch process includes using a chlorine or chlorine-containing plasma to etch the implanted region 411 in FIGS. 7B and 7C. The etchants enter the trench 431 and etch the silicon material of the implanted region 411, while leaving the un-implanted p-type silicon regions largely unetched.

The source for the chlorine plasma includes Cl₂, CCl₄, etc. Absolute rates for the intrinsic reaction between Cl atoms and surfaces of silicon doped with phosphorus (P), arsenic (As), or antimony (Sb) is a function of dopant concentration (Ne) and substrate temperature (T). When there is no ion bombardment, increasing Ne increases the Si—Cl reaction rate even when silicon is lightly doped. The etch rate (ER) can be expressed as follow.

$$E R ( A / min ) = {vN}_{e}^{y} {n}_{Cl} {T}^{1 / 2} {e}^{- {E}_{a} / kT}$$

where:
n_{Cl} is the gas phase Cl concentration,
T is the temperature,
Ea is the activation energy, and
νN^{γ}ₑ is the preexponential factor. (νNγe)
   Some aspects of the selective etching process have been described, for example, in “Doping and crystallographic effects in Cl-atom etching of silicon,” E. Ogryzlo, Journal of Applied Physics, April 1990, herein incorporated by reference in its entirety.

In some embodiments, the selective etch includes cycles of chlorine plasma etch followed by a purge. Due to the influence of crystal orientation on the etch rate, the cavity 441 may exhibit facets on the sidewalls, depending on the process conditions.

FIG. 9A is a top view and FIGS. 9B-9D are various cross-sectional views illustrating another intermediate process of a method for forming a semiconductor device, in accordance with some embodiments. In process 360, method 300 includes disposing an insulating material in the trench and the cavity, which form the recess under the epitaxial region. FIG. 9A is a top view of the device structure showing an insulating material 451 disposed in the trench 431 shown in FIG. 8A. FIG. 9A also shows the epitaxial layer 421 and the epitaxial layer 424, which is the portion of the epitaxial layer 421 in the device region 410 that is isolated from the rest of the epitaxial layer 421 and the substrate 401.

FIG. 9A shows two cut lines C1-C1′ and C2-C2′. FIG. 9B is a cross-sectional view of the device structure of FIG. 9A along cut line C1-C1′, and FIG. 9C is a cross-sectional view along cut line C2-C2′ shown in FIG. 9A. FIG. 9B also shows a third cut line C3-C3′, and FIG. 9D is a cross-sectional view of the device structure along cut line C3-C3′ in FIG. 9B. FIGS. 9A-9D illustrate a semiconductor device including a semiconductor substrate 401 and a recess 442 formed by trench 431 and cavity 441 in the semiconductor substrate 401. An insulating material 451 is disposed in the recess 442 including trench 431 and cavity 441. A portion of the semiconductor substrate 401 protruding from a bottom 443 of the recess forms a semiconductor pillar 404, which is surrounded by the recess. A single crystalline semiconductor layer 424 is disposed on the pillar 404. As shown in FIG. 9B, the single crystalline semiconductor layer 424 is in direct contact with the semiconductor substrate 401 through the pillar 404, and the single crystalline semiconductor layer 424 is otherwise isolated from the semiconductor substrate 401 by the recess 442.

The insulating material 451 can be silicon oxide, silicon nitride, silicon oxynitride, fluoride-doped silicate glass (FSG), or another low dielectric constant (low-k) dielectric material. The trench and cavity may be filled with the insulating material using a deposition process, such as atomic layer deposition (ALD) process, a high aspect-ratio chemical vapor deposition (CVD) process, flowable CVD (FCVD) process, or another suitable process. The deposition process can be followed by a planarization process, such as a chemical-mechanical polishing (CMP) process or an etching process.

As shown in FIGS. 9A-9D, an insulator material will be disposed in the cavity 442. Therefore, the single crystalline semiconductor layer 424 is an example of a silicon-on-insulator or semiconductor-on-insulator (SOI) structure. As described above, the single crystalline semiconductor layer 424 is formed by a silicon epitaxial growth process. Therefore, the term “single crystalline” as used herein refers to the layer of epitaxial silicon, subject to the crystalline quality achievable by the epitaxial process.

In the examples described above, each SOI structure is supported by one pillar protruding from the substrate. In some embodiments, the device can include additional pillars in the recess, the additional pillars connecting the single crystalline semiconductor layer to the semiconductor substrate. An example is described below with reference to FIGS. 10A-10C.

FIG. 10A is a top view and FIGS. 10B-10C are cross-sectional views illustrating a semiconductor device, in accordance with some embodiments. FIG. 10A shows two cut lines C1-C1′ and C2-C2′. FIG. 10B is a cross-sectional view of the device structure of FIG. 10A along cut line C1-C1′. FIG. 10B also shows a third cut line C3-C3′, and FIG. 10C is a cross-sectional view of the device structure along cut line C3-C3′ in FIG. 10B.

FIGS. 10A-10C illustrate a semiconductor device including a semiconductor substrate 401 and a recess 442 formed by trench 431 and cavity 441 in the semiconductor substrate 401. An insulating material 451 is disposed in the recess 442 including trench 431 and cavity 441. A portion of the semiconductor substrate 401 protruding from a bottom 443 of the recess forms semiconductor pillars 404-1, 404-2, 404-3, and 404-4, each of which is surrounded by the insulating material 451 in the recess. A single crystalline semiconductor layer 424 is disposed on the pillars 404-1 to 404-4. As shown in FIG. 10B, the single crystalline semiconductor layer 424 is in direct contact with the semiconductor substrate 401 through the pillars 404-1 to 404-4, and the single crystalline semiconductor layer 424 is otherwise isolated from the semiconductor substrate 401 by the insulating material 451 in the recess 442.

As described below in FIGS. 10A-10C, an insulator material 451 is disposed in the cavity 442. Therefore, the single crystalline semiconductor layer 424 is an example of a silicon-on-insulator or semiconductor-on-insulator (SOI) structure. Therefore, the single crystalline semiconductor layer 424 is also referred to as an SOI layer 424. As described above, the single crystalline semiconductor layer 424 is formed by a silicon epitaxial growth process. Therefore, the term “single crystalline” as used herein refers to the layer of epitaxial silicon, subject to the crystalline quality achievable by the epitaxial process.

In some embodiments, the device region 410 in the semiconductor substrate includes additional un-implanted regions for forming more than one pillar. For example, in FIG. 5A, the mask 460 can have more than one blocked region 462. In this case, more than one pillar are formed, and the epitaxial region is connected with the semiconductor substrate through two or more pillars, as shown in FIGS. 10A-10C. In some embodiments, as shown in FIG. 5A, the open region 461 of mask 460 completely surrounds the blocked region 462. In alternative embodiments, the open region 461 may not completely surround the blocked region 462. For example, the blocked region 462 may extend to an edge of device region 410. In this case, after the trench 431 is formed surrounding the device region, as described below with reference to FIGS. 7A-7C, the un-implanted region 412 will be separated from the substrate by the trench.

Referring back to the method 300 outlined in the flowchart of FIG. 3, at process 370, the method includes performing further processing to form a capacitor device. An example of such a capacitor device is described above in connection to FIGS. 1, 2A, and 2B. In FIGS. 1, 2A, and 2B, the SOI layer 424 is formed on pillar 404 in the p-well 401, which is referred to as substrate 401 in the description of method 300. The SOI layer 424 is surrounded by insulation material 451 in the trench 431 and the cavity 441 in the p-well. Subsequently, the SOI layer 424 is doped with n-type impurities to form an n+ region to be a bottom plate of the capacitor device. A capacitor dielectric layer 426 is disposed on the bottom plate, and a top plate 428 is disposed on the capacitor dielectric layer 426.

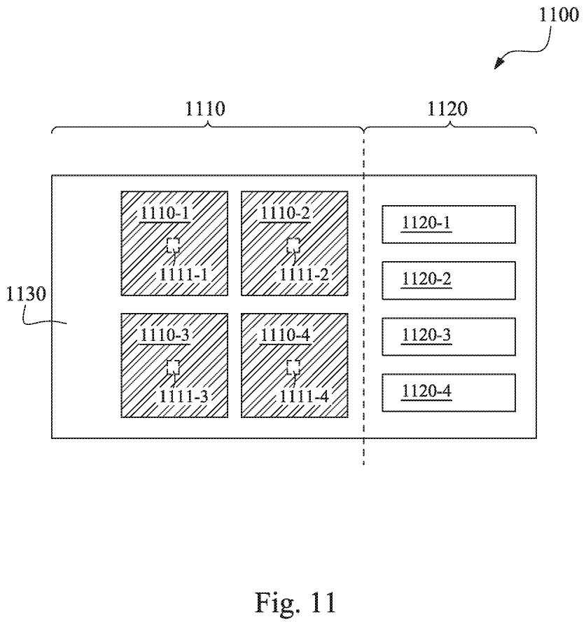

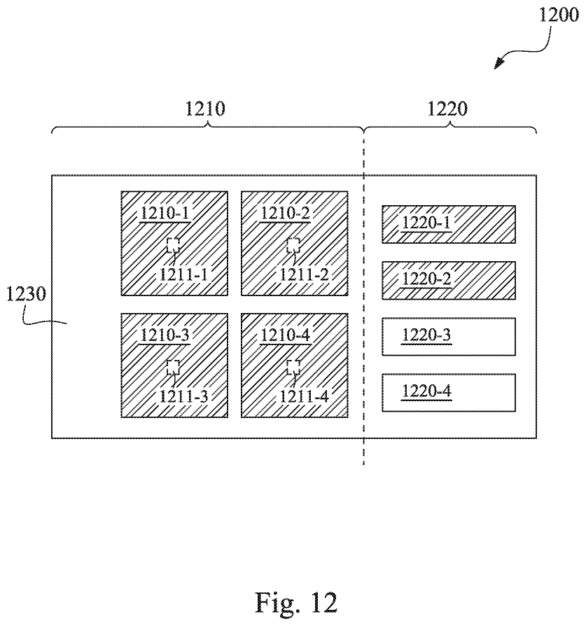

The embedded SOI structures described above in connection with FIGS. 1-10C can be embedded in a standard CMOS process on a standard silicon wafer, when only part of the device can benefit from the SOI structure. For example, the embedded SOI structures can be embedded in different integrated circuits, which are not suited to be fabricated on an SOI wafer, or do not need to be fabricated on an SOI wafer. Some examples are described below with reference to FIGS. 11 and 12.

FIG. 11 is a simplified layout diagram illustrating an example of an integrated circuit including embedded SOI regions, in accordance with some embodiments. As shown in FIG. 11, integrated circuit 1100 includes an MOS array region 1110 and a logic circuit region 1120. The MOS array region 1110 includes embedded SOI regions 1110-1, 1110-2, 1110-3, and 1110-4, etc. The logic circuit region 1120 includes active regions 1120-1, 1120-2, 1130-3, and 1140-4, etc. A trench isolation 1130 surrounds and isolates the embedded SOI regions and the active regions described above. Even though four embedded SOI regions and four active regions are shown in FIG. 11, it is understood that any number of embedded SOI regions and active regions can be formed in integrated circuit 1100.

Each of the embedded SOI regions 1110-1 to 1110-4 includes a SOI layer similar to the crystalline layer 424 as shown in FIG. 1, which is disposed on an insulating layer formed by a cavity filled with insulating material 451. Each of the embedded SOI regions 1110-1 to 1110-4 also includes a pillar that is disposed underneath the crystalline region and connected to the substrate (not shown), similar to the pillar 404 described above in connection with FIG. 1. In some embodiments, each of the embedded SOI regions 1110-1 to 1110-4 is configured as a capacitor with an SOI layer as the lower capacitor plate, as illustrated in FIGS. 1-10C.

Each of the active regions 1120-1 to 1120-4 includes a semiconductor region in the substrate which is configured for semiconductor circuits. Even though the active regions 1120-1 to 1120-4 are referred to as being in the logic circuit region 1120, the semiconductor circuits in these regions are not limited to the logic circuit. For example, the semiconductor circuits in these regions can include digital, analog, mixed-signal circuits, etc. The semiconductor circuits in these regions can include embedded memories, etc.

FIG. 12 is a simplified layout diagram illustrating another example of an integrated circuit including embedded SOI regions, in accordance with some embodiments. As shown in FIG. 12, integrated circuit 1200 includes an MOS array region 1210 and a logic circuit region 1220. The MOS array region 1210 includes embedded SOI regions 1210-1, 1210-2, 1210-3, and 1210-4, etc. The logic circuit region 1220 includes active regions 1220-1, 1220-2, 1230-3, and 1240-4, etc. A trench isolation 1230 surrounds and isolates the embedded SOI regions and the active regions described above.

Each of the embedded SOI regions 1210-1 to 1210-4 includes an SOI layer similar to the crystalline layer 424 as shown in FIG. 1, which is disposed on an insulating layer formed by a cavity filled with insulating material 451. Each of the embedded SOI regions 1210-1 to 1210-4 also includes a pillar that is disposed underneath the crystalline region and connected to the substrate (not shown), similar to the pillar 404 described above in connection with FIG. 1. In some embodiments, each of the embedded SOI regions 1210-1 to 1210-4 is configured as a capacitor with an SOI layer as the lower capacitor plate, as illustrated in FIGS. 1-10C.

Each of the active regions 1220-1 and 1220-2 includes an embedded SOI layer similar to the crystalline layer 424 as shown in FIG. 1, which is disposed on an insulating layer formed by a cavity filled with insulating material 451 with a pillar (not shown). In some embodiments, each of the active regions 1220-1 and 1220-2 includes an embedded SOI layer without a pillar. Such an embedded SOI layer can be made, starting with the embedded SOI structure 424 described in FIGS. 9A-9C, by forming another trench isolation to remove the pillar 404. Since the cavity 441 and trench 431 are now filled with insulating material 451, there is no concern about the SOI layer 424 peeling off. Alternatively, an embedded SOI region can be formed without a pillar using other methods. One such method is described with reference to FIGS. 8A-8C. In some embodiments, the trench 431 does not completely surround the implanted region 411.

Each of the active regions 1220-3 to 1220-4 includes a semiconductor region in the substrate which is configured for semiconductor circuits. As shown in FIG. 12, login circuit region 1220 includes embedded SOI regions 1220-1 and 1220-2 and standard active regions 1220-3 and 1220-4 in the substrate. Even though the active regions 1220-1 to 1220-4 are referred to as being in the logic circuit region 1220, the semiconductor circuits in these regions are not limited to the logic circuit. For example, the semiconductor circuits in these regions can include digital, analog, mixed-signal circuits, etc. The semiconductor circuits in these regions can include embedded memories, etc. The embedded SOI regions 1220-1 and 1220-2 can be used for forming certain circuits that can benefit from the isolated thinner substrate and less capacitance.

In accordance with some embodiments, an embedded SOI (silicon-on-insulator or semiconductor-on-insulator) structure is formed and used in an MOS capacitor structure for reducing the leakage. A method is provided for forming the embedded SOI structure in a selected regions of a semiconductor substrate. In some embodiments, the selected region is implanted with n-type dopants to form an implanted region and an un-implanted region. An epitaxial layer is formed over the implanted region. A trench is formed that surrounds the selected region to expose at least a portion of the implanted region. A selective silicon lateral etching process is used to remove the implanted region to create a cavity under the epitaxial layer. The trench and the cavity are filled with an insulation material. The epitaxial layer in the selected region now resides over the insulating material, forming an SOI structure. The un-implanted region is retained during the selective etching process to form a pillar protruding from the substrate and connects the epitaxial layer to the substrate. The pillar connects the epitaxial layer to the substrate during the selective etching process to prevent the epitaxial layer from peeling off. The SOI structure is heavily n-type doped and serves as a bottom plate for capacitor device. A benefit of this method is that the reduced contact between the n+ bottom plate and the substrate can reduce the capacitor leakage could be greatly reduced by the SOI structure, which is isolated from the substrate, except at the pillar. Further, the method for the embedded SOI structure can be used to embed SOI regions in selected areas in a standard CMOS integrated circuit on a bulk substrate, providing flexibility in circuit and device design. Depending on the embodiments, the embedded SOI region can have one or more pillars. In some embodiments, the embedded SOI region has no pillar.

According to some embodiments, a method for forming a semiconductor device includes providing a semiconductor substrate, which includes p-type impurities, implanting n-type impurities into a device region in the semiconductor substrate to form an implanted region and an un-implanted region in the device region. The method includes forming an epitaxial layer on the device region in the semiconductor substrate and forming a trench surrounding the device region. The trench extends through the epitaxial layer into the semiconductor substrate, and the trench is in direct contact with the implanted region. The method also includes performing a selective lateral etch through the trench to remove the implanted region to form a cavity under the epitaxial layer in the device region. The un-implanted region is retained to form a pillar under the epitaxial layer. Further, the method includes disposing an insulating material in the cavity and the trench. The method forms a single crystalline region that is separated from the semiconductor substrate by the insulating material except at the pillar.

According to some embodiments, a capacitor device includes a semiconductor substrate and a recess in the semiconductor substrate. An insulating material is disposed in the recess. The capacitor device also includes a semiconductor pillar protruding from the semiconductor substrate and surrounded by the insulating material. A single crystalline semiconductor region is disposed on the semiconductor pillar and the insulating material surrounding the pillar to form a bottom plate of the capacitor device. The capacitor device includes a capacitor dielectric layer disposed on the bottom plate and a top plate disposed on the capacitor dielectric layer.

According to some embodiments, a semiconductor device includes a semiconductor substrate and a recess in the semiconductor substrate. A portion of the semiconductor substrate protrudes from a bottom of the recess to form a semiconductor pillar. A single crystalline semiconductor layer is disposed on the pillar. The single crystalline semiconductor layer is in direct contact with the semiconductor substrate through the pillar, and is otherwise separated from the semiconductor substrate by the recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
providing a semiconductor substrate, the semiconductor substrate comprising p-type impurities;
implanting n-type impurities into a device region in the semiconductor substrate to form an implanted region and an un-implanted region in the device region;
forming an epitaxial layer on the device region in the semiconductor substrate;
forming a trench surrounding the device region, the trench extending through the epitaxial layer into the semiconductor substrate, the trench being in direct contact with the implanted region;
performing a selective lateral etch through the trench to remove the implanted region to form a cavity under the epitaxial layer in the device region, wherein the un-implanted region is retained to form a pillar under the epitaxial layer; and
disposing an insulating material in the cavity and the trench;
thereby forming a single crystalline region that is separated from the semiconductor substrate by the insulating material except at the pillar.

2. The method of claim 1, wherein the device region in the semiconductor substrate comprises additional un-implanted regions.

3. The method of claim 2, wherein the epitaxial layer is connected with the semiconductor substrate through two or more pillars.

4. The method of claim 1, wherein the implanted region completely surrounds the un-implanted region.

5. The method of claim 1, wherein performing the selective lateral etch comprises using an etch process that has etch selectivity of etching n-type semiconductor material over p-type semiconductor material.

6. The method of claim 1, wherein performing the selective lateral etch comprises using a chlorine plasma to etch the implanted region.

7. The method of claim 1, wherein the semiconductor substrate comprises a p-well formed in an n-well.

8. The method of claim 1, further comprising doping the epitaxial layer into an n+ region to form a bottom plate of a capacitor.

9. The method of claim 8, further comprising forming a dielectric layer on the epitaxial layer.

10. The method of claim 9, further comprising forming a top plate of the capacitor on the dielectric layer.

11. The method of claim 1, wherein the single crystalline region comprises a single crystalline semiconductor layer disposed on and attached to a top surface of the pillar.

12. A method for forming a capacitor device, comprising:
providing a semiconductor substrate;
forming a semiconductor layer on the semiconductor substrate;
forming a recess in the semiconductor substrate under the semiconductor layer, wherein the recess defines a semiconductor pillar protruding from a bottom of the recess, and wherein a portion of the semiconductor layer is retained on the semiconductor pillar to form a single crystalline semiconductor region serving as a bottom plate of the capacitor device;
disposing an insulating material in the recess, wherein the semiconductor pillar is surrounded by the insulating material;
forming a capacitor dielectric layer on the bottom plate; and
forming a top plate on the capacitor dielectric layer.

13. The method of claim 12, wherein the capacitor dielectric layer is in direct contact with the bottom plate and is disposed between the bottom plate and the top plate.

14. The method of claim 12, wherein forming the recess comprises:
forming a trench extending through the semiconductor layer into the semiconductor substrate; and
subsequently performing a selective lateral etch through the trench to form a cavity under the semiconductor layer.

15. The method of claim 12, wherein the semiconductor pillar and the single crystalline semiconductor region are structurally defined simultaneously during the forming of the recess.

16. The method of claim 12, wherein the recess is formed by performing a selective lateral etch in the semiconductor substrate.

17. A method for forming a semiconductor structure, comprising:
providing a substrate comprising a well region;
forming a semiconductor layer on the well region;
forming a recess within the well region under the semiconductor layer, wherein the recess defines a semiconductor pillar extending therethrough, and wherein a portion of the semiconductor layer is retained on the semiconductor pillar to form an isolated semiconductor layer anchored to the well region by the semiconductor pillar;
disposing an insulating material in the recess to form an embedded insulating layer; and
forming a capacitor stack on the isolated semiconductor layer, the capacitor stack comprising a capacitor dielectric and a top plate, wherein the isolated semiconductor layer is configured to serve as a bottom plate of a capacitor.

18. The method of claim 17, wherein the capacitor dielectric is in direct contact with the isolated semiconductor layer and is disposed between the isolated semiconductor layer and the top plate.

19. The method of claim 17, further comprising forming an isolation structure surrounding the isolated semiconductor layer.

20. The method of claim 19, wherein forming the recess comprises:
forming a trench extending through the semiconductor layer into the well region; and
performing a selective lateral etch through the trench to form a cavity in the well region under the semiconductor layer,
wherein the cavity defines the semiconductor pillar; and
wherein disposing the insulating material in the recess comprises:
simultaneously disposing the insulating material into the cavity to form the embedded insulating layer and into the trench to form the isolation structure.
